(19) United States
(12) Patent Application Publication
(10) Pub. No.: US 2025/0344595 A1
(43) Pub. Date: Nov. 6, 2025

(54) DISPLAY DEVICE

(71) Applicant: Samsung Display Co., Ltd., Yongin-si (KR)

(72) Inventors: TAEYOUNG SONG, Yongin-si (KR); YOUNGSOO KWON, Yongin-si (KR); WON-GAP YOON, Yongin-si (KR); KIHEON LEE, Yongin-si (KR)

(21) Appl. No.: 19/194,496

(22) Filed: Apr. 30, 2025

(30) Foreign Application Priority Data
May 2, 2024 (KR) 10-2024-0058372

(51) Int. Cl. H10K 59/80; H10K 59/122; H10K 59/38; H10K 102/00

(52) U.S. Cl. CPC H10K 59/878; H10K 59/122; H10K 59/38; H10K 2102/331

(57) ABSTRACT

A display device including a base layer, first and second light emitting elements on the base layer and each emitting a source light is provided. A display device includes a first partition wall through which a first opening is defined to correspond to the first light emitting element, a first light control pattern disposed in the first opening, a reflective layer disposed on at least an inner side surface of the first partition wall, which defines the first opening, and a color layer disposed on the reflective layer to overlap at least the inner side surface of the first partition wall and absorbing a light incident thereto from an outside.

### CROSS-REFERENCE TO RELATED APPLICATION

This application claims priority to and the benefit of Korean Patent Application No. 10-2024-0058372, filed on May 2, 2024, in the Korean Intellectual Property Office, the entire disclosure of which is incorporated herein by reference.

### BACKGROUND

### 1. Field

One or more aspects of embodiments of the present disclosure relate to a display device. More particularly, the present disclosure relates to a display device including a light control pattern.

### 2. Description of Related Art

Display devices can be categorized into two main types (kinds): transmissive display devices, which selectively transmit light from an external source; and emissive display devices, which generate their own light. These devices incorporate various functional patterns within their pixels to produce images. These functional patterns either transmit specific wavelength ranges of the source light or alter the color of the source light.

### SUMMARY

One or more aspects of embodiments of the present disclosure are directed toward a display device with improved (enhanced) light emission efficiency. However, aspects of the present disclosure are not restricted to those set forth herein.

The preceding and other aspects of the present disclosure will become more apparent to one of ordinary skill in the art to which the present disclosure pertains by referencing the detailed description of the present disclosure.

One or more embodiments of the present disclosure provide a display device including a first base layer, first and second light emitting elements arranged on the first base layer and each emitting a source light, (e.g., first and second light emitting elements on the first base layer, and each being configured to emit a source light). The display device includes a first partition wall through which a first opening is defined to correspond to the first light emitting element, a first light control pattern arranged in the first opening, a reflective layer arranged on at least an inner side surface of the first partition wall, which (that) defines the first opening, and a color layer arranged on the reflective layer and being to overlap at least the inner side surface of the first partition wall and absorbing a light incident thereto from an outside.

The reflective layer may be further arranged on an upper surface of the first partition wall.

The color layer may be arranged on the reflective layer to further overlap the upper surface of the first partition wall.

The reflective layer may include a first portion arranged on the inner side surface of the first partition wall and a second portion overlapping the upper surface of the first partition wall, and the color layer may entirely overlap the first portion and the second portion.

The display device may further include a second partition wall through which (e.g., comprising) a second opening may be defined to correspond to the second light emitting element and a second light control pattern arranged in the second opening. The reflective layer may be further arranged on an inner side surface of the second partition wall, which defines the second opening, and the color layer may be arranged on the reflective layer to further overlap the inner side surface of the second partition wall.

The reflective layer may be further arranged on an outer side surface of the first partition wall.

The color layer may be arranged on the reflective layer to further overlap the outer side surface of the first partition wall.

The source light may be a blue light.

The first light control pattern may include a quantum dot to convert the blue light to a red light or a yellow light.

The color layer may have the same color as the source light (e.g., a color of the color layer may be the same as a color of the source light.).

The first partition wall may include a light shielding material.

The reflective layer may include at least one selected from the metal group consisting of aluminum, silver, gold, platinum, copper, and palladium.

The display device may further include a thin film encapsulation layer arranged on the first base layer and configured to encapsulate the first and second light emitting elements, and the first partition wall may be arranged on the thin film encapsulation layer.

The display device may further include a first color filter arranged on the first light control pattern, and the first color filter may have a color different from the color of the color layer.

The display device may further include a first color filter arranged on the first light control pattern an encapsulation panel opposite to (e.g., facing) the first base layer, and the first color filter may be arranged on a lower surface of the encapsulation panel.

One or more embodiments of the present disclosure provide a display device including a base layer, first and second light emitting elements arranged on the base layer and each emitting a source light, (e.g., configured to each emit a source light). The display device includes a partition wall through which an opening is defined to correspond to the first light emitting element, a light control pattern arranged in the opening, and a reflective layer configured (e.g., arranged to correspond) to an outer side surface of the partition wall and an upper surface of the partition wall. The partition wall may have a color that is substantially the same color as a color of the source light.

The partition wall may be configured to transmit the source light and absorbs a light incident thereto from an outside of the display device.

The display device may further include a color filter arranged on the light control pattern.

According to one or more embodiments, an electronic device may include the display device of the present disclosure.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

According to the present disclosure, the source light may be reflected by the reflected layer arranged to correspond to the inner side surface of the partition wall and may be provided back to the light control pattern. The effect of recycling the source light may be improved and the light emission efficiency of the display device may be enhanced thereby.

According to the present disclosure, the color layer arranged on the reflective layer may absorb the light incident from the outside, and thus, the reflectance of the external light may be reduced thereby.

According to the present disclosure, the reflective layer and/or the partition wall may prevent or reduce the color mixture between pixel areas adjacent to each other. As a result, an accurate grayscale representation may be achieved by the display device of the present disclosure.

For example, the present disclosure describes how a reflective layer, positioned along the inner side surface of a partition wall, may enhance light recycling and improve the light emission efficiency of a display device. Additionally, a color layer on the reflective layer may absorb external light, reducing its reflectance. The reflective layer and/or partition wall may also help prevent or reduce color mixing between adjacent pixel areas, resulting in more accurate grayscale representation.

### BRIEF DESCRIPTION OF THE DRAWINGS

The accompanying drawings are included to provide a further understanding of the preceding and other advantages of the present disclosure and are incorporated in and constitute a part of this specification. The drawings illustrate example embodiments that will become readily apparent with reference to the following detailed description when considered in conjunction with the accompanying drawings wherein:

FIG. 1A is a perspective view of a display device according to one or more embodiments of the present disclosure;

FIG. 1B is a cross-sectional view of a display device according to one or more embodiments of the present disclosure;

FIG. 2 is a plan view of a display panel according to one or more embodiments of the present disclosure;

FIG. 3 is an equivalent circuit diagram of a pixel according to one or more embodiments of the present disclosure;

FIGS. 4A and 4B are enlarged plan views of a display area according to one or more embodiments of the present disclosure;

FIG. 5A is a cross-sectional view of a display device taken along a line I-I′ of FIG. 4A;

FIGS. 5B and 5C are schematic cross-sectional views illustrating effects of improving luminance and reducing reflectance according to one or more embodiments of the present disclosure;

FIGS. 6A and 6B are plan views illustrating a shape of partition walls according to one or more embodiments of the present disclosure;

FIG. 6C is a plan view illustrating a shape of a color layer according to one or more embodiments of the present disclosure;

FIG. 7 is a cross-sectional view of a display device taken along a line I-I′ of FIG. 4A; and

FIGS. 8 and 9 are cross-sectional views of display devices according to one or more embodiments of the present disclosure.

### DETAILED DESCRIPTION

The present disclosure will now be described and may be embodied in many different forms and should thus not be construed as limited to one or more embodiments set forth herein. Rather, these embodiments are provided so that this disclosure will be thorough and complete, and will fully convey the scope of present disclosure to those skilled in the art.

In the present disclosure, it will be understood that when an element (or area, layer, or portion) is referred to as being “on”, “connected to” or “coupled to” another element or layer, it may be directly on, connected or coupled to the other element or layer or intervening elements or layers may be present.

Like numerals refer to like elements throughout, and duplicative descriptions thereof may not be provided. In the drawings, the thickness, ratio, and dimension of components are exaggerated for effective description of the technical content. As used herein, the term “and/or” may include any and all combinations of one or more of the associated listed items.

Expressions such as “at least one of,” “one of,” “selected from,” and “selected from among,” when preceding a list of elements, modify the entire list of elements and do not modify the individual elements of the list. For example, throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

It will be understood that, although the terms first, second, and/or the like may be used herein to describe one or more suitable elements, these elements should not be limited by these terms. These terms are only used to distinguish one element from another element. Thus, a first element could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and/or the like, may be used herein for ease of description to describe one element or feature's relationship to another elements or features as shown in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

It will be further understood that the terms “comprises,” “comprising,” “comprise,” “has,” “have,” “having,” “includes,” “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including chemical, technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

In this context, “consisting essentially of” indicates that any additional components will not materially affect the chemical, physical, optical or electrical properties of the semiconductor film.

Hereinafter, embodiments of the present disclosure will be described with reference to accompanying drawings in which one or more embodiments of present disclosure are shown. An aspect and a characteristic of the disclosure, and a method of accomplishing these will be apparent referring to one or more embodiments described with reference to the drawings. In this specification, phrases such as “on a plane,” “plan view,” and/or the like indicate viewing a target portion from the top, and the phrase “on a cross-section” indicates viewing a cross-section formed by vertically cutting a target portion from the side

### Display Device

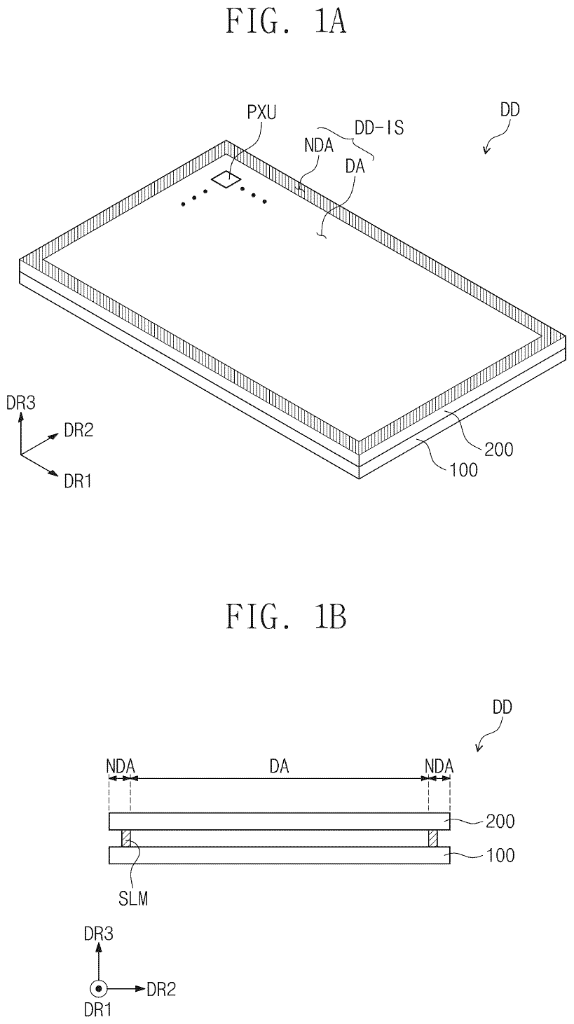

FIG. 1A is a perspective view of a display device DD according to one or more embodiments of the present disclosure. FIG. 1B is a cross-sectional view of the display device DD according to one or more embodiments of the present disclosure.

Referring to FIG. 1A, the display device DD may display an image through a display surface DD-IS. The display surface DD-IS may be substantially parallel to a plane defined by a first direction DR1 and a second direction DR2. An upper surface of a member arranged at an uppermost position of the display device DD may be defined as the display surface DD-IS.

A third direction DR3 may indicate a normal line direction of the display surface DD-IS, i.e., a thickness direction of the display device DD. Front (or upper) and rear (or lower) surfaces of each layer or each unit may be distinguished from each other in the third direction DR3. In the present context and unless defined otherwise, “plan view” or “in a plan view” refers to a view looking down onto the display surface DD-IS from above, where the plane of the view is parallel to the first direction DR1 and the second direction DR2, and perpendicular or normal to the third direction DR3.

The display device DD may include a display area DA and a non-display area NDA. Unit pixels PXU may be arranged in the display area DA, and the unit pixels PXU may not be arranged in the non-display area NDA. The non-display area NDA may be defined along an edge of the display surface DD-IS. The non-display area NDA may be around (e.g., surround) the display area DA. According to one or more embodiments, the non-display area NDA may not be provided or may be defined adjacent to only one side of the display area DA. FIG. 1A shows a flat display device DD as a representative example, however, the display device DD may have a curved shape, may be rolled, or may be slid from a housing.

The unit pixels PXU shown in FIG. 1A may define a pixel row and a pixel column. The unit pixel PXU may be the smallest repeating unit and may include at least one pixel. The unit pixel PXU may include a plurality of pixels that provide lights having different colors from each other.

Referring to FIG. 1B, the display device DD may include a display panel 100 (or a lower display substrate) and an encapsulation panel 200 (or an upper display substrate) opposite to (e.g., facing) the display panel 100 and spaced and/or apart (e.g., spaced apart or separated) from the display panel 100. A set or predetermined cell gap may be defined between the display panel 100 and the encapsulation panel 200. The cell gap may be maintained by a sealing member SLM coupling the display panel 100 and the encapsulation panel 200. The sealing member SLM may include a binder resin and inorganic fillers mixed with the binder resin. The sealing member SLM may further include other additives. The additives may include an amine-based curing agent and/or a photoinitiator. The additives may further include a silane-based additive and/or an acrylic-based additive. The sealing member SLM may include an inorganic-based material such as a frit.

Referring to FIG. 1B, each of the display panel 100 and the encapsulation panel 200 may include a display area DA and a non-display area NDA defined therein to be the same as the display area DA and the non-display area NDA of the display device DD. Hereinafter, the display area DA of the display device DD may indicate the display area DA of each of the display panel 100 and the encapsulation panel 200, and the non-display area NDA of the display device DD may indicate the non-display area NDA of each of the display panel 100 and the encapsulation panel 200.

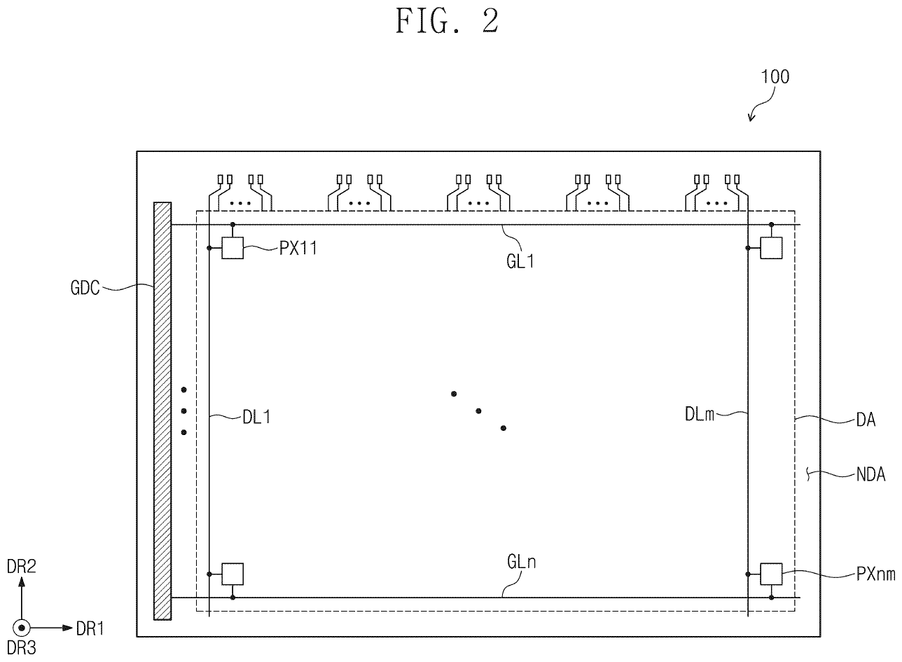

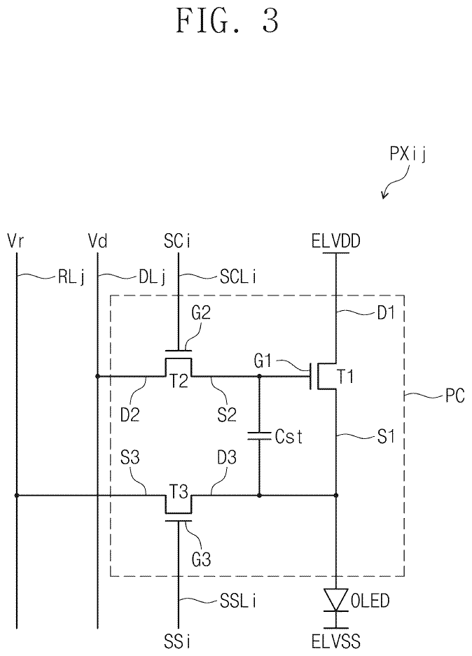

FIG. 2 is a plan view of the display panel 100 according to one or more embodiments of the present disclosure, and FIG. 3 is an equivalent circuit diagram of a pixel PXij according to one or more embodiments of the present disclosure.

FIG. 2 shows an arrangement relationship of signal lines GL1 to GLn and DL1 to DLm and pixels PX11 to PXnm on a plan view. The signal lines GL1 to GLn and DL1 to DLm may include a plurality of scan lines GL1 to GLn and a plurality of data lines DL1 to DLm.

Each of the pixels PX11 to PXnm may be connected to a corresponding scan line among the scan lines GL1 to GLn and a corresponding data line among the data lines DL1 to DLm. Each of the pixels PX11 to PXnm may include a pixel circuit and a light emitting element. More types (kinds) of signal lines may be provided in the display panel 100 according to a configuration of the pixel circuit of each of the pixels PX11 to PXnm.

FIG. 3 shows the pixel PXij connected to an i-th scan line SCLi, an i-th sensing line SSLi, a j-th data line DLj, and a j-th reference line RLj as a representative example. The pixel PXij may include a pixel circuit PC and a light emitting element OLED electrically connected to the pixel circuit PC. The pixel circuit PC may include a plurality of transistors T1 to T3 and a capacitor Cst. The transistors T1 to T3 may be formed through a low temperature polycrystalline silicon (LTPS) process or a low temperature polycrystalline oxide (LTPO) process. Hereinafter, the transistors T1 to T3 will be described as an N-type (kind) transistor, however, they should not be limited thereto or thereby. According to one or more embodiments, at least one of the transistors T1 to T3 may be a P-type (kind) transistor.

In the present embodiment, the pixel circuit PC including a first transistor T1 (a driving transistor), a second transistor T2 (a switching transistor), a third transistor T3 (a sensing transistor), and the capacitor Cst is shown as a representative example. However, the pixel circuit PC should not be limited thereto or thereby. According to one or more embodiments, the pixel circuit PC may further include an additional transistor or may further include an additional capacitor.

The light emitting element OLED may be an organic light emitting element, which includes an anode (a first electrode) and a cathode (a second electrode), and/or an inorganic light emitting element. The anode of the light emitting element OLED may receive a first voltage ELVDD via the first transistor T1, and the cathode of the light emitting element OLED may receive a second voltage ELVSS. The light emitting element OLED may be to emit the light in response to the first voltage ELVDD and the second voltage ELVSS.

The first transistor T1 may include a drain D1 receiving the first voltage ELVDD, a source S1 connected to the anode of the light emitting element OLED, and a gate G1 connected to the capacitor Cst. The first transistor T1 may control a driving current flowing from the first voltage ELVDD to the light emitting element OLED in response to a level of a voltage charged in the capacitor Cst.

The second transistor T2 may include a drain D2 connected to the j-th data line DLj, a source S2 connected to the capacitor Cst, and a gate G2 receiving an i-th first scan signal SCi. The j-th data line DLj may receive a data voltage Vd. The second transistor T2 may apply the data voltage Vd to the first transistor T1 in response to the i-th first scan signal SCi.

The third transistor T3 may include a source S3 connected to the j-th reference line RLj, a drain D3 connected to the anode of the light emitting element OLED, and a gate G3 receiving an i-th second scan signal SSi. The j-th reference line RLj may receive a reference voltage Vr. The third transistor T3 may initialize the capacitor Cst and the anode of the light emitting element OLED.

The capacitor Cst may be charged with electric charges corresponding to a difference between the voltage from the second transistor T2 and the first voltage ELVDD. The capacitor Cst may be connected to the gate G1 of the first transistor T1 and the anode of the light emitting element OLED.

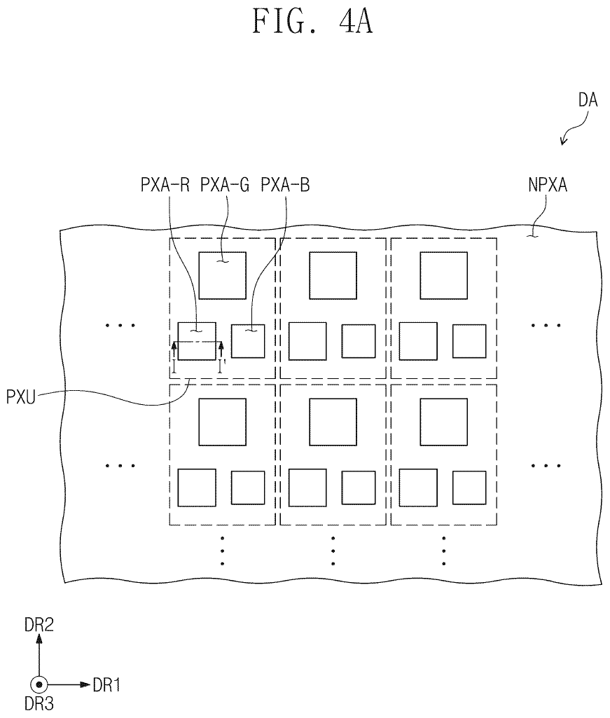

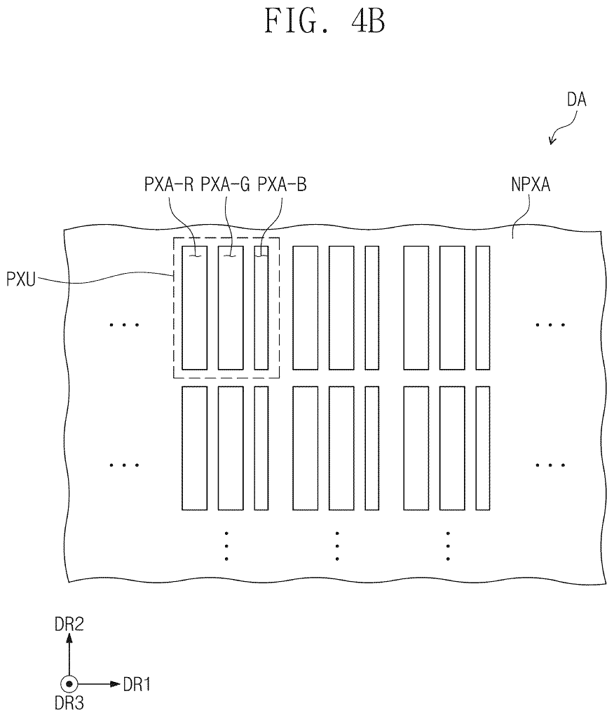

FIGS. 4A and 4B are enlarged plan views of the display area DA according to one or more embodiments of the present disclosure.

Referring to FIGS. 4A and 4B, the unit pixels PXU may be arranged in the first direction DR1 and the second direction DR2. In the present embodiment, the unit pixel PXU may include a first pixel, a second pixel, and a third pixel, which emit lights having different colors from each other. The first pixel, the second pixel, and the third pixel may be to emit a red light, a green light, and a blue light, respectively. FIGS. 4A and 4B show a first pixel area PXA-R, a second pixel area PXA-G, and a third pixel area PXA-B as representative examples of the first pixel, the second pixel, and the third pixel, respectively. A peripheral area NPXA may be defined between the first, second, and third pixel areas PXA-R, PXA-G, and PXA-B. The peripheral area NPXA may define a boundary of the first, second, and third pixel areas PXA-R, PXA-G, and PXA-B and may prevent or reduce a color mixture between the first, second, and third pixel areas PXA-R, PXA-G, and PXA-B.

Referring to FIG. 4A, the first pixel area PXA-R and the third pixel area PXA-B may be arranged in substantially the same row, and the second pixel area PXA-G may be arranged in a row different from the row in which the first pixel area PXA-R and the third pixel area PXA-B are arranged. The second pixel area PXA-G may have the largest size, and the third pixel area PXA-B may have the smallest size, however, the present disclosure should not be limited thereto or thereby. In the present embodiment, each of the first pixel area PXA-R, the second pixel area PXA-G, and the third pixel area PXA-B has a substantially quadrangular shape, however, it should not be particularly limited.

Referring to FIG. 4B, the first pixel area PXA-R, the second pixel area PXA-G, and the third pixel area PXA-B may be arranged in substantially the same row. The first pixel area PXA-R, the second pixel area PXA-G, and the third pixel area PXA-B may have substantially the same width in the second direction DR2.

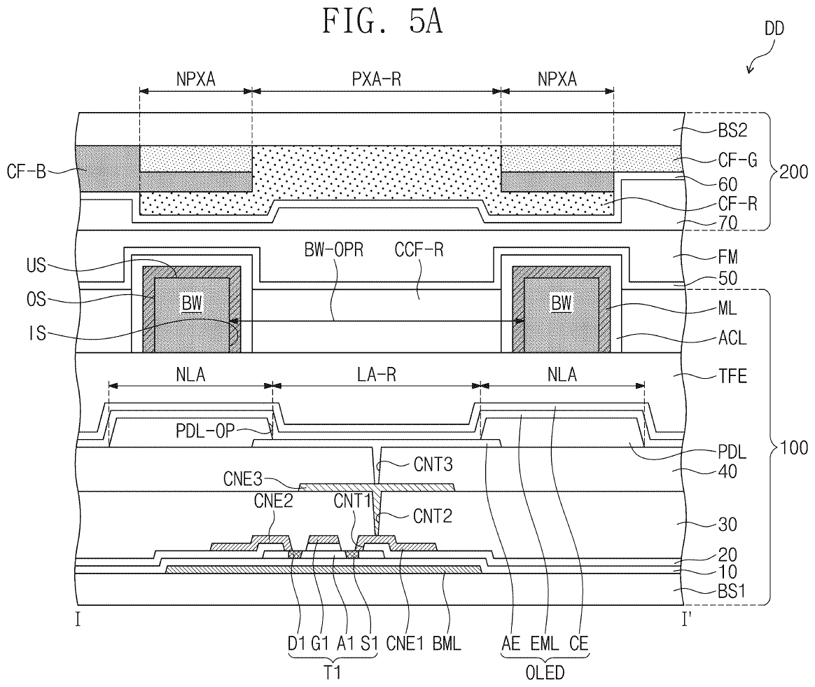

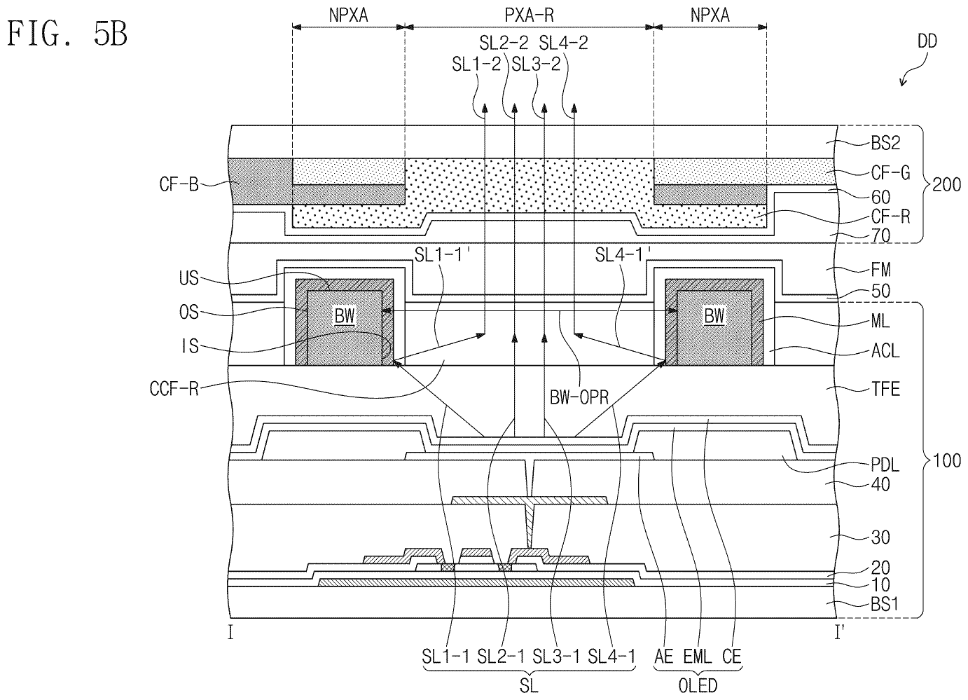

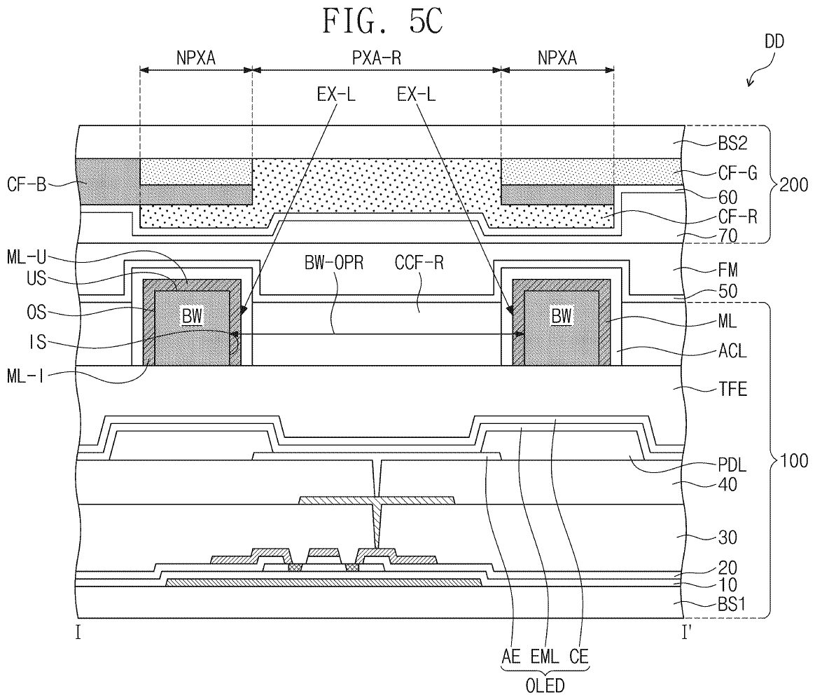

FIG. 5A is a cross-sectional view of the display device DD taken along a line I-I′ of FIG. 4A, and FIGS. 5B and 5C are schematic cross-sectional views illustrating effects of improving luminance and reducing reflectance according to one or more embodiments of the present disclosure.

FIG. 5A shows a detailed cross-sectional view of the display panel 100 and the encapsulation panel 200 centered on the first pixel area PXA-R. Referring to FIG. 5A, a filling material FM may be arranged between the display panel 100 and the encapsulation panel 200, however, the present disclosure should not be limited thereto or thereby. According to one or more embodiments, the filling material FM may not be provided, and a gap may be defined between the display panel 100 and the encapsulation panel 200. The filling material FM may be an organic material, but it should not be particularly limited.

A light blocking pattern BML may be arranged on a first base layer BL1. The light blocking pattern BML may include a metal material. A signal line may be arranged on the same layer as the light blocking pattern BML. A first insulating layer 10 may be arranged on the first base layer BL1 to cover the light blocking pattern BML.

A semiconductor pattern may be arranged on the first insulating layer 10 to overlap the light blocking pattern BML. The semiconductor pattern may have different electrical properties depending on whether it is doped or not. The semiconductor pattern may include a first region having a relatively high conductivity and a second region having a relatively low conductivity. The first region may be doped with an N-type (kind) dopant or a P-type (kind) dopant. A P-type (kind) transistor may include a doped region doped with the P-type (kind) dopant, and an N-type (kind) transistor may include a doped region doped with the N-type (kind) dopant. The second region may be a non-doped region or a region doped at a concentration lower than that of the first region.

The semiconductor pattern may include a source S1, a channel A1 (or an active), and a drain D1. A second insulating layer 20 may be arranged on the first insulating layer 10. Contact holes CNT1 may be defined through the second insulating layer 20 to expose the source S1 and the drain D1. Each of the first insulating layer 10 and the second insulating layer 20 may be an inorganic layer.

Connection electrodes CNE1 and CNE2 may be arranged on the second insulating layer 20. A first connection electrode CNE1 may electrically connect the source S1 of the first transistor T1 to the drain D3 of the third transistor T3 shown in FIG. 3. A second connection electrode CNE2 may electrically connect the drain D1 of the first transistor T1 to the signal line receiving the first voltage ELVDD shown in FIG. 3. In FIG. 5A, the signal line may be configured to receive the first voltage ELVDD.

A third insulating layer 30 may be arranged on the second insulating layer 20. A third connection electrode CNE3 may be arranged on the third insulating layer 30. The third connection electrode CNE3 may be connected to the first connection electrode CNE1 via a contact hole CNT2 defined through the third insulating layer 30. A fourth insulating layer 40 may be arranged on the third insulating layer 30. An anode AE may be arranged on the fourth insulating layer 40. The anode AE may be connected to the third connection electrode CNE3 via a contact hole CNT3 defined through the fourth insulating layer 40. The third insulating layer 30 and/or the fourth insulating layer 40 may be an organic layer.

The light emitting element OLED and a pixel definition layer PDL may be arranged on the fourth insulating layer 40. The pixel definition layer PDL may be provided with an opening PDL-OP defined therethrough to expose at least a portion of the anode AE. The opening PDL-OP of the pixel definition layer PDL may define a first light emitting area LA-R. An area in which the pixel definition layer PDL is arranged may be defined as a non-light-emitting area NLA.

Referring to FIG. 4A, light emitting areas may be defined to respectively correspond to the first pixel area PXA-R, the second pixel area PXA-G, and the third pixel area PXA-B. In the present embodiment, a light emitting area corresponding to the first pixel area PXA-R may be defined as the first light emitting area LA-R.

A light emitting layer EML may be commonly arranged over the first light emitting area LA-R and the non-light-emitting area NLA. The light emitting layer EML may be to emit a source light. The light emitting layer EML may include an organic light emitting material or an inorganic light emitting material. In the present embodiment, the source light may be a blue light. In the present embodiment, the blue light may be referred to as a first color light. A common layer such as the light emitting layer EML may be arranged to overlap the unit pixels PXU of the display area DA shown in FIG. 4A. A cathode CE may be arranged on the light emitting layer EML. The cathode CE may be commonly arranged over the first light emitting area LA-R and the non-light-emitting area NLA.

In one or more embodiments, a hole control layer may be arranged under the light emitting layer EML. An electron control layer may be arranged between the light emitting layer EML and the cathode CE. The electron control layer may include an electron transport layer and/or an electron injection layer. Each of the cathode CE, the hole control layer, and the electron control layer may correspond to the common layer.

A thin film encapsulation layer TFE may be arranged on the cathode CE. The thin film encapsulation layer TFE may be commonly arranged over plural pixels PXij as shown in FIG. 3. In the present embodiment, the thin film encapsulation layer TFE may directly cover the cathode CE.

The thin film encapsulation layer TFE may include at least one inorganic layer and/or organic layer. In the present embodiment, the thin film encapsulation layer TFE may include two inorganic layers and an organic layer arranged between the two inorganic layers. According to one or more embodiments, the thin film encapsulation layer TFE may include a plurality of inorganic layers and/or a plurality of organic layers alternately stacked with the inorganic layers.

A partition wall BW (or referred to as a partition pattern) may be arranged on the thin film encapsulation layer TFE. In the present embodiment, the partition wall BW may include a base resin and/or an additive. The base resin may include one or more suitable resin compositions. The additive may include a coupling agent and/or a photoinitiator. The additive may further include a dispersant. The partition wall BW may include a material having a transmittance equal to or smaller than a set or predetermined value. As an example, the partition wall BW may include a light shielding material, e.g., a black coloring agent. The partition wall BW may include a base resin and a black dye or pigment mixed with the base resin. As an example, the partition wall BW may include at least one selected from among (e.g., of) propylene glycol methyl ether acetate, 3-methoxy-n-butyl acetate, acrylate monomer, acrylic monomer, organic pigment, and acrylate ester.

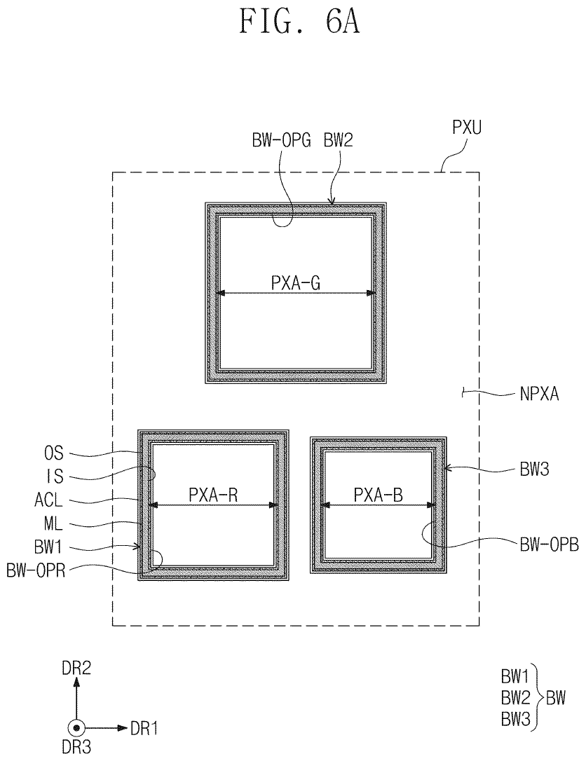

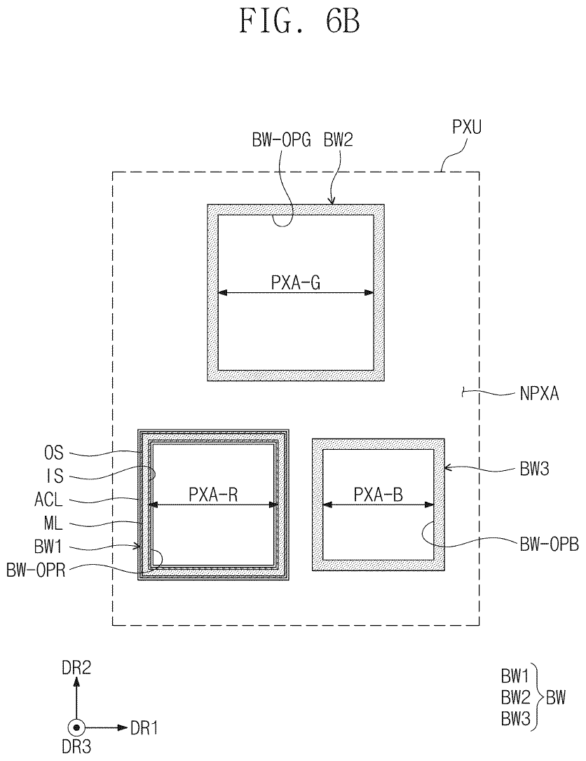

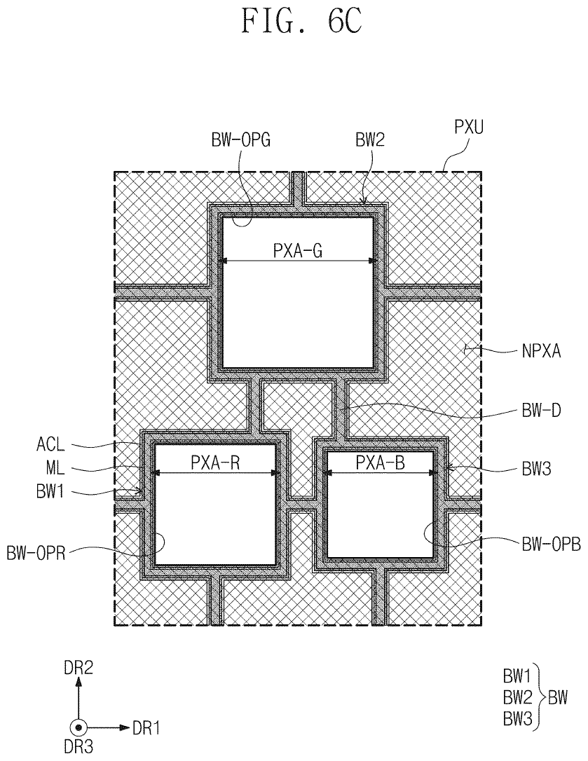

The partition wall BW may be arranged in the non-light-emitting area NLA. In one or more embodiments, the partition walls may be arranged to correspond to the first pixel area PXA-R, the second pixel area PXA-G, and the third pixel area PXA-B shown in FIG. 4A, respectively. Each of the partition walls may define an opening. In the present embodiment, the partition wall corresponding to the first pixel area PXA-R may be referred to as a first partition wall BW1 as shown in FIG. 6a. Hereinafter, the first partition wall BW1 as shown in FIG. 6a may be referred to as the same as the partition wall BW as shown in FIG. 5A to 5C. A first opening BW-OPR may be defined through the first partition wall BW1.

A boundary between side surfaces IS and OS of the first partition wall BW1 and an upper surface US of the first partition wall BW1 may be unclear. An area of a surface of the first partition wall BW1, which is not in contact with the thin film encapsulation layer TFE and parallel to the first base layer BS1, may be referred to as the upper surface US, an area that is slant to the first base layer BS1 if (e.g., when) viewed in the cross-section (in a cross-sectional view) and faces a first light control pattern CCF-R may be referred to as an inner side surface IS, and an area that is slant to the first base layer BS1 if (e.g., when) viewed in the cross-section and does not face the first light control pattern CCF-R may be referred to as an outer side surface OS.

A reflective layer ML may be arranged on at least the inner side surface IS of the first partition wall BW1. In some embodiments, the reflective layer ML may be further arranged on the upper surface US of the first partition wall BW1. In the present embodiment, the reflective layer ML may also be arranged on the outer side surface OS of the first partition wall BW1, however, the present disclosure should not be limited thereto or thereby. The reflective layer ML may overlap the non-light-emitting area NLA and may not overlap the first light emitting area LA-R.

The reflective layer ML may include a metal material with a relatively high reflectance. As an example, the reflective layer ML may include at least one selected from the metal group consisting of aluminum, silver, gold, platinum, copper, and palladium. For instance, the reflective layer ML may include aluminum.

A color layer ACL may be arranged on the reflective layer ML to overlap at least the inner side surface IS of the first partition wall BW1. The color layer ACL may further overlap at least the upper surface US of the first partition wall BW1. The color layer ACL may further overlap at least the outer side surface OS of the first partition wall BW1. The color layer ACL may completely cover the reflective layer ML.

The color layer ACL may include a base resin and/or an additive. The color layer ACL may include one or more suitable resin compositions. The color layer ACL may include a dye and/or pigment. The color layer ACL may have a set or predetermined color due to the dye and/or pigment. As an example, the color layer ACL may have a blue or green color and may have the same color as the source light.

The first light control pattern CCF-R may be arranged in the first opening BW-OPR of the first partition wall BW1. The first light control pattern CCF-R may be in contact with the color layer ACL. The first light control pattern CCF-R may change optical properties of the source light. In the present embodiment, the first light control pattern CCF-R may be to absorb the source light emitted from the light emitting element OLED and then may generate a light having a different color. In the present embodiment, the light generated by the first light control pattern CCF-R may be referred to as a second color light, and the second color light may be a red light or a yellow light.

The first light control pattern CCF-R may include a base resin, quantum dots mixed with (or dispersed in) the base resin, and scattering particles mixed with (or dispersed in) the base resin. According to one or more embodiments, the scattering particles may not be provided.

The base resin may be a medium in which the quantum dots are dispersed and may include one or more suitable resin compositions that are generally referred to as a binder, however, it should not be limited thereto or thereby. In the present disclosure, any medium in which the quantum dots are dispersed may be referred to as the base resin regardless of its name, additional functions, materials, and/or the like. The base resin may be a polymer resin. For example, the base resin may be an acrylic-based resin, a urethane-based resin, a silicone-based resin, and/or an epoxy-based resin. The base resin may be a transparent resin.

The quantum dots may be particles that change a wavelength of light incident thereto. The quantum dots are a material having a crystal structure of several nanometers in size, contain hundreds to thousands of atoms, and exhibit a quantum confinement effect in which an energy band gap increases due to a small size. When a light having a wavelength with an energy higher than the band gap is incident to the quantum dots, the quantum dots absorb the light and become excited, and then, the quantum dots emit a light of a specific wavelength and fall to a ground state. The emitted light of the specific wavelength has an energy value corresponding to the band gap. The light-emitting property of the quantum dots due to the quantum confinement effect may be controlled or selected by adjusting the size and the composition of the quantum dots.

A core of the quantum dots may be selected from among a group II-VI compound, a group III-VI compound, a group III-V compound, a group III-II-V compound, a group IV-VI compound, a group I-III-VI compound, a group I-IV-VI compound, a group IV element, a group IV compound, and/or a (e.g., any suitable) combination thereof.

The group II-VI compound may be selected from among a binary compound selected from the group consisting of CdS, CdSe, CdTe, ZnS, ZnSe, ZnTe, ZnO, HgS, HgSe, HgTe, MgSe, MgS, and/or a (e.g., any suitable) mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or a (e.g., any suitable) mixture thereof, and a quaternary compound selected from the group consisting of CdZnSeS, CdZnSeTe, CdZnSTe, CdHgSeS, CdHgSeTe, CdHgSTe, HgZnSeS, HgZnSeTe, HgZnSTe, and/or a (e.g., any suitable) mixture thereof.

The group III-VI compound may include a binary compound, such as In2S3, In2Se3, and/or the like, a ternary compound, such as InGaS3, InGaSe3, and/or the like, or any combination thereof.

The group III-V compound may be selected from among a binary compound selected from the group consisting of GaN, GaP, GaAs, GaSb, AlN, AlP, AlAs, AlSb, InN, InP, InAs, InSb, and/or a (e.g., any suitable) mixture thereof, a ternary compound selected from the group consisting of GaNP, GaNAs, GaNSb, GaPAs, GaPSb, AlNP, AlNAs, AlNSb, AlPAS, AlPSb, InGaP, InAlP, InNP, InNAs, InNSb, InPAs, InPSb, and/or a (e.g., any suitable) mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or a (e.g., any suitable) mixture thereof. The group III-V compound may further include a group II metal. For instance, InZnP may be selected as a group III-II-V compound.

The group IV-VI compound may be selected from among a binary compound selected from the group consisting of SnS, SnSe, SnTe, PbS, PbSe, PbTe, and/or a (e.g., any suitable) mixture thereof, a ternary compound selected from the group consisting of SnSeS, SnSeTe, SnSTe, PbSeS, PbSeTe, PbSTe, SnPbS, SnPbSe, SnPbTe, and/or a (e.g., any suitable) mixture thereof, and a quaternary compound selected from the group consisting of SnPbSSe, SnPbSeTe, SnPbSTe, and/or a (e.g., any suitable) mixture thereof. The group IV element may be selected from the group consisting of Si, Ge, and/or a (e.g., any suitable) mixture thereof. The group IV compound may be a binary compound selected from the group consisting of SiC, SiGe, and/or a (e.g., any suitable) mixture thereof.

The group I-III-VI compound may include a ternary compound selected from the group consisting of AgInS2, CuInS2, AgGaS2, CuGaS2, and/or a (e.g., any suitable) mixture thereof, or a quaternary compound of AgInGaS2, CuInGaS2, and/or the like.

In this case, the binary compound, the ternary compound, or the quaternary compound may exist in the particles at a substantially uniform concentration or may exist in substantially the same particle after being divided into plural portions having different concentrations. In some embodiments, the quantum dots may have a core/shell structure in which one quantum dot surrounds another quantum dot. In the core/shell structure, the concentration of elements existing in the shell may have a concentration gradient that is lowered as a distance from the core decreases.

In one or more embodiments, the quantum dot may have a core-shell structure that includes a core including the herein-mentioned nanocrystal and a shell around (e.g., surrounding) the core. The shell of the quantum dot may serve as a protective layer to prevent or reduce chemical modification of the core and to maintain semiconductor properties and/or may serve as a charging layer to impart electrophoretic properties to the quantum dot. The shell may have a single-layer or multi-layer structure. The shell of the quantum dot may include metal oxides, non-metal oxides, semiconductor compounds, and/or one or more (e.g., any suitable) combinations thereof as its representative example.

The metal oxides or non-metal oxides may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or a (e.g., any suitable) mixture thereof, or a ternary compound, such as MgAl₂O₄, CoFe₂O₄, NiFe₂O₄, CoMn₂O₄, and/or a (e.g., any suitable) mixture thereof, however, they should not be limited thereto or thereby.

In some embodiments, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or a (e.g., any suitable) mixture thereof, however, they should not be limited thereto or thereby.

The quantum dots may be particles with size on the nanometer scale. The quantum dots may have a full-width at half-maximum (FWHM) of a light emission wavelength spectrum of about 45 nanometer (nm) or less, about 40 nm or less, or about 30 nm or less. The color purity and the color reproducibility may be improved within this range. In some embodiments, because the light emitted through the quantum dots may be emitted in all directions, an optical viewing angle may be improved.

The quantum dots may have a shape commonly used in the art, and it should not be particularly limited. In more detail, spherical, pyramidal, multi-arm, or cubic nanoparticles, nanotubes, nanowires, nanofibers, nanoplatelets, and/or the like may be applied to the quantum dots. The quantum dots may control the color of the emitted light depending on a particle size thereof, and accordingly, the quantum dots may have one or more suitable emission colors such as blue, red, and green colors.

The scattering particles may scatter a light generated by a light control pattern or a light passing through the light control pattern. The scattering particles may be particles with a relatively high density or specific gravity. The scattering particles may include titanium oxide (TiO₂) or silica-based nanoparticles.

A fifth insulating layer 50 may be arranged on the color layer ACL. The fifth insulating layer 50 may encapsulate the color layer ACL and the first light control pattern CCF-R. The fifth insulating layer 50 may include an inorganic layer.

The encapsulation panel 200 may be arranged to face the display panel 100. Color filters CF-R, CF-G, and CF-B may be arranged on a lower surface of a second base layer BS2. An area in which two or more color filters among a first color filter CF-R, a second color filter CF-G, and a third color filter CF-B are arranged to overlap each other may be defined as the peripheral area NPXA. The first pixel area PXA-R of FIG. 4A may be defined as an area in which only the first color filter CF-R among the color filters CF-R, CF-G, and CF-B is arranged.

A sixth insulating layer 60 may be arranged under the color filters CF-R, CF-G, and CF-B. The sixth insulating layer 60 may encapsulate the color filters CF-R, CF-G, and CF-B and may include an inorganic layer. A seventh insulating layer 70 may be arranged under the sixth insulating layer 60. The seventh insulating layer 70 may provide a flat surface and may include an organic layer.

### Method of Manufacturing the Display Device

Hereinafter, a method of manufacturing the display device DD will be described.

Referring to FIG. 5A, the manufacturing method of the display device DD includes forming the display panel 100, forming the encapsulation panel 200, and coupling the display panel 100 with the encapsulation panel 200. A method of forming the thin film encapsulation layer TFE and elements arranged under the thin film encapsulation layer TFE of the display panel 100 should not be particularly limited, and thus, details thereof will not be provided.

The first partition wall BW1 may be formed on the thin film encapsulation layer TFE of the display panel 100. In this case, the first opening BW-OPR may be formed through the first partition wall BW1. A preliminary partition wall layer may be formed on the thin film encapsulation layer TFE, and then a photoresist layer may be formed on the preliminary partition wall layer. Then, exposure, development, and etching processes may be performed on the preliminary partition wall layer to form the first partition wall BW1. Through substantially the same processes, a second partition wall and a third partition wall, which respectively correspond to the second pixel area PXA-G and the third pixel area PXA-B shown in FIG. 4A, may be formed. The reflective layer ML may be formed on the first partition wall BW1. The reflective layer ML may be formed to correspond to the inner side surface IS of the first partition wall BW1. The reflective layer ML may be formed to correspond to the outer side surface OS and the upper surface US of the first partition wall BW1. For instance, a preliminary reflective layer may be formed by a sputtering process. A photoresist layer may be formed on the preliminary reflective layer. Then, the preliminary reflective layer may be patterned by exposure, development, and etching processes to form the reflective layer ML.

The color layer ACL may be formed on the reflective layer ML. A preliminary color layer may be formed to cover the first partition wall BW1 and the reflective layer ML, and a photoresist layer may be formed on the preliminary color layer. Then, exposure, development, and etching processes may be performed on the preliminary color layer to form the color layer ACL. An area where the color layer ACL is formed may be determined depending on a placement of a mask pattern formed from the photoresist layer. The color layer ACL may be formed on the reflective layer ML to overlap the inner side surface IS of the first partition wall BW1. The color layer ACL may be formed on the reflective layer ML to overlap the outer side surface OS and the upper surface US of the first partition wall BW1.

The first light control pattern CCF-R may be formed in the first opening BW-OPR. The first light control pattern CCF-R may be formed through an inkjet process. A first resin composition, which is in liquid form and mixed with a first quantum dot, may be provided in the first opening BW-OPR. Then, the first resin composition may be cured.

The fifth insulating layer 50 may be formed to cover the first light control pattern CCF-R and the first partition wall BW1. The fifth insulating layer 50 may be formed by depositing an inorganic material or organic material through a deposition process. The process of forming the fifth insulating layer 50 may not be provided.

Hereinafter, a method of forming the encapsulation panel 200 is described. The first color filter CF-R may be formed on the second base layer BS2 to overlap the first pixel area PXA-R. The first color filter CF-R may overlap the peripheral area NPXA. An organic layer including the dye or pigment may be formed, and a photoresist layer may be formed on the organic layer. Then, exposure, development, and etching processes may be performed on the organic layer to form the first color filter CF-R.

The second color filter CF-G and the third color filter CF-B may be formed through processes similar to those of the first color filter CF-R. The second color filter CF-G and the third color filter CF-B may overlap a corresponding pixel area and a corresponding peripheral area NPXA.

The sixth insulating layer 60 may be arranged under the color filters CF-R, CF-G, and CF-B. The sixth insulating layer 60 with a low refractive index may be formed by co-depositing hollow inorganic particles and an inorganic material. The seventh insulating layer 70 may be formed under the sixth insulating layer 60 through a deposition process. The seventh insulating layer 70 may act as a planarization and encapsulation layer.

Referring to FIG. 5B, the source light SL emitted from the light emitting element OLED may be emitted upwardly. Some source lights SL2-1 and SL3-1 may be provided to the first light control pattern CCF-R arranged inside the first opening BW-OPR, and a color of the source lights SL2-1 and SL3-1 may be converted by the quantum dot included in the in first light control pattern CCF-R. The other source lights SL1-1 and SL4-1 may be reflected by the reflective layer ML arranged to correspond to the inner side surface IS of the first opening BW-OPR, and the reflected lights SL1-1′ and SL4-1′ may be provided again to the first light control pattern CCF-R. Colors of the reflected lights SL1-1′ and SL4-1′ may be converted by the quantum dot included in the first light control pattern CCF-R. The source lights SL1-1 and SL4-1 whose colors are not converted in the first light control pattern CCF-R may be reflected by the reflective layer ML and may be incident to the first light control pattern CCF-R. Accordingly, the light conversion efficiency of the source light SL may be improved, and a front brightness may be improved.

The first partition wall BW1 including the black coloring agent may prevent or reduce the source light SL from passing through the first partition wall BW1. In some embodiments, the reflective layer ML may prevent or reduce the source light SL from passing through the first partition wall BW1. Therefore, a light leakage or interference between pixels, which occurs if (e.g., when) the light generated in one light emitting area passes through the first partition wall BW1 and is incident to the light control pattern arranged in an adjacent light emitting area, may be prevented or reduced.

Referring to FIG. 5C, the color layer ACL may be to absorb a portion of a light EX-L (hereinafter, referred to as an external light) incident thereto from the outside of the display panel 100 and may reduce the external light EX-L incident to the reflective layer ML. The first color filter CF-R may be to transmit the red light in natural light, and the red light passing through and exiting from the first color filter CF-R may be absorbed by the color layer ACL. Accordingly, a reflection phenomenon in which the red light incident from the outside is reflected by the reflective layer ML and then travels back to the outside may be prevented or reduced.

As the color layer ACL covers the reflective layer ML to overlap the upper surface US of the first partition wall BW1, the reflection of the external light incident to the upper surface US of the first partition wall BW1 may be further reduced.

The reflective layer ML may include a first portion ML-I arranged on the inner side surface IS and outer side surface OS of the first partition wall BW1 and a second portion ML-U overlapping the upper surface US of the first partition wall BW1, and the color layer ACL may entirely overlap the first portion ML-I and the second portion ML-U. As the color layer entirely overlaps the first portion ML-I and the second portion ML-U, the reflection of the external light, which is caused by the reflective layer ML, may be prevented or reduced.

Table 1 shows measured values for the light emission efficiency (%) of the display device DD and the reflectance (%) of the external light of the display device DD. Comparative example 1 shows a display device that does not include the reflective layer ML and the color layer ACL described with reference to FIGS. 5A to 5C. Comparative example 2 shows a display device that includes the reflective layer ML described with reference to FIGS. 5A to 5C but does not include the color layer ACL. One or more example embodiments show the display device that includes the reflective layer ML and the color layer ACL described with reference to FIG. 5A.

In Table 1, the light emission efficiency (%) is measured using a source light of about 450 nm and is expressed as a relative value, with the light emission efficiency of comparative example 1 set at 100%. The reflectance (%) of the external light is measured by a transmitted light using a D65 light source and is expressed as a relative value, with the reflectance of comparative example 1 set at 100%. An SCI (Specular Component Included) is the result of measuring a specular light that is incident and reflected and a diffused light, and an SCE (Specular Component Excluded) is the result of measuring a diffused light that is incident and reflected. A light that is incident and reflected at the same angle may be referred to as the specular light, and a light that is scattered and reflected in multiple directions may be referred to as the diffused light.

TABLE 1

| | Light emission | Reflectance of external light | |
|---|---|---|---|
| | efficiency (%) | CI (%) | CE (%) |
| Comparative example 1 | 100 | 100 | 100 |
| Comparative example 2 | 140 | 138 | 181 |
| Embodiment example | 127 | 101 | 101 |

Referring to the results of Table 1, it is observed that the light emission efficiency of the Embodiment example may be improved compared to comparative example 1, and the reflectance of the external light of the Embodiment example may be reduced compared to comparative example 2. For example, if (e.g., when) the reflective layer ML is arranged to correspond to the inner side surface IS of the partition wall BW, the light emission efficiency and the luminance may be improved by a recycling effect of the source light. In addition, according to the present disclosure, because the color layer ACL (e.g., arranged to correspond to the inner side surface IS of the partition wall BW) absorbs the portion of the external light, the reflectance of the external light may be reduced. For example, arranging the reflective layer ML along the inner side surface IS of the partition wall BW enhances light emission efficiency and luminance through light recycling. Additionally, the color layer ACL positioned along the inner side surface IS of the partition wall BW absorbs external light, further reducing its reflectance.

In FIGS. 5A to 5C, the description focuses on the first pixel area PXA-R, but the second pixel area PXA-G and the third pixel area PXA-B of FIG. 4A may also have a cross-sectional structure similar to that of the first pixel area PXA-R. The second partition wall and the third partition wall may be arranged to correspond to the second pixel area PXA-G and the third pixel area PXA-B, respectively, and a second light control pattern and a scattering pattern may be arranged in an opening of the second partition wall and an opening of the third partition wall, respectively.

The second light control pattern may convert the source light into a third color light. The third color light may be a green light. The second light control pattern may include quantum dots to convert the blue light into the green light. The scattering pattern may be to transmit the source light without converting the source light. In this case, the scattering pattern may scatter the source light to improve a viewing angle.

FIGS. 6A and 6B are plan views illustrating a shape of partition walls BW according to one or more embodiments of the present disclosure, and FIG. 6C is a plan view illustrating a shape of the color layer ACL according to one or more embodiments of the present disclosure.

FIG. 6A shows the first partition wall BW1 defining the first opening BW-OPR corresponding to the first pixel area PXA-R, the second partition wall BW2 defining a second opening BW-OPG corresponding to the second pixel area PXA-G, and a third partition wall BW3 defining a third opening BW-OPB corresponding to the third pixel area PXA-B as a representative example. The first partition wall BW1, the second partition wall BW2, and the third partition wall BW3 may be arranged spaced and/or apart (e.g., spaced apart or separated) from each other. Each of the pixel areas PXA-R, PXA-G, and PXA-B may have substantially the same size as that of a corresponding opening among the openings BW-OPR, BW-OPG, and BW-OPB, however, the present disclosure should not be limited thereto or thereby. The reflective layer ML and the color layer ACL may be arranged to overlap an inner side surface IS and an outer side surface OS of each of the first partition wall BW1, the second partition wall BW2, and the third partition wall BW3.

The reflective layer ML and the color layer ACL may be arranged to overlap an upper surface of each of the first partition wall BW1, the second partition wall BW2, and the third partition wall BW3. However, FIG. 6A shows the upper surface of each of the first partition wall BW1, the second partition wall BW2, and the third partition wall BW3 if (e.g., when) viewed in the third direction DR3 to distinguish the reflective layer ML and the color layer ACL from the first partition wall BW1, the second partition wall BW2, and the third partition wall BW3.

Referring to FIG. 6B, a reflective layer ML and a color layer ACL may be arranged to overlap an inner side surface IS and an outer side surface OS of a first partition wall BW1. According to the present embodiment, different from the partition wall BW shown in FIG. 6A, the reflective layer ML and the color layer ACL may be arranged to overlap only one partition wall BW1 among first to third partition walls BW1 to BW3.

Different from the partition walls BW shown in FIGS. 6A and 6B, a partition wall BW-D (hereinafter, referred to as an additional partition wall) connected to a first partition wall BW1, a second partition wall BW2, and a third partition wall BW3 may be further arranged around the first partition wall BW1, the second partition wall BW2, and the third partition wall BW3. This is shown in FIG. 6C as a representative example.

FIG. 6C shows a color layer ACL overlapping the first partition wall BW1, the second partition wall BW2, and the third partition wall BW3. FIG. 6C shows a structure in which a reflective layer ML is not arranged on an upper surface of each of the first partition wall BW1, the second partition wall BW2, and the third partition wall BW3, however, the reflective layer ML may be arranged on the upper surface of each of the first partition wall BW1, the second partition wall BW2, and the third partition wall BW3.

In FIG. 6C, the reflective layer ML may be arranged on the upper surface of the first partition wall BW1, the second partition wall BW2, and the third partition wall BW3 as shown in FIG. 5A. The color layer ACL and the reflective layer ML may overlap the additional partition wall BW-D, and the color layer ACL and the reflective layer ML may be arranged between the first partition wall BW1, the second partition wall BW2, and the third partition wall BW3.

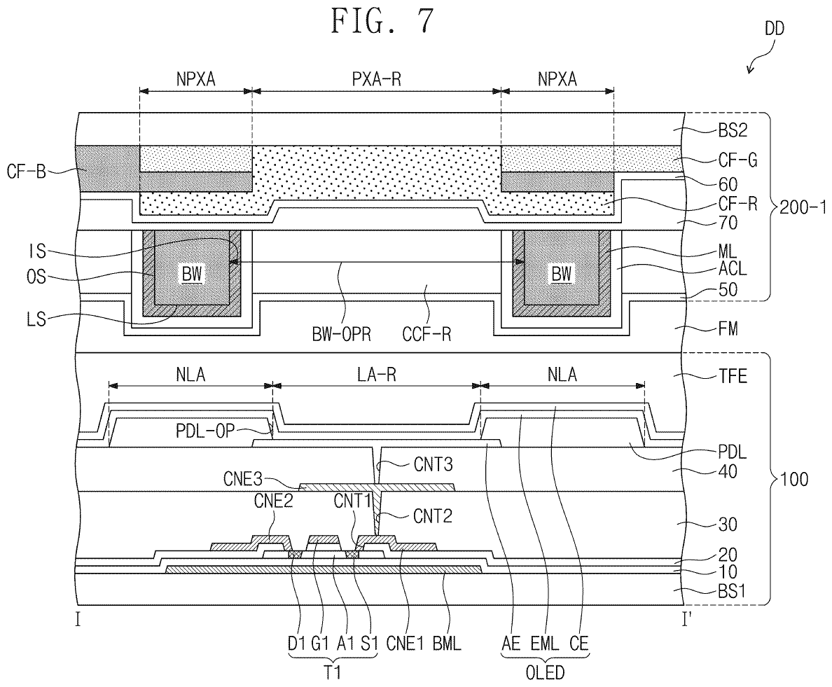

FIG. 7 is a cross-sectional view of a display device DD taken along a line I-I′ of FIG. 4A. In FIG. 7, detailed descriptions of the same elements as those described with reference to FIGS. 1A to 5C will not be provided and descriptions will be focused on different features from those of the display device DD described with reference to FIGS. 5A to 5C.

A light conversion panel 200-1 of FIG. 7 may correspond to the encapsulation panel 200 of FIG. 5A. The light conversion panel 200-1 of FIG. 7 may include a first color filter CF-R, a sixth insulating layer 60, and a seventh insulating layer 70, which are arranged above a second base layer BS2. The light conversion panel 200-1 may further include a partition wall BW, a reflective layer ML, a color layer ACL, a first light control pattern CCF-R, and a fifth insulating layer 50, which are additionally arranged under the seventh insulating layer 70, if (e.g., when) compared to the encapsulation panel 200 FIG. 5A.

The seventh insulating layer 70 may provide a flat surface thereunder. The partition wall BW through which a first opening BW-OPR is defined may be arranged under the flat surface.

An area of a surface of the partition wall BW, which is not in contact with the seventh insulating layer 70 and faces the second base layer BS2, may be defined as a lower surface LS, an area of the surface of the partition wall BW, which is slant with respect to the second base layer BS2 and faces the first light control pattern CCF-R, may be defined as an inner side surface IS, and an area of the surface of the partition wall BW, which is slant with respect to the second base layer BS2 and does not face the first light control pattern CCF-R, may be defined as an outer side surface OS.

As described with reference to FIG. 5A, the reflective layer ML may be arranged on at least the inner side surface IS of the partition wall BW. The reflective layer ML may be further arranged on the lower surface LS of the partition wall BW. In the present embodiment, the reflective layer ML may also be arranged on the outer side surface OS of the partition wall BW, however, the present disclosure should not be limited thereto or thereby. The reflective layer ML may overlap a non-light-emitting area NLA and may not overlap a first light emitting area LA-R.

The color layer ACL may be arranged on the reflective layer ML to overlap at least the inner side surface IS of the partition wall BW. The color layer ACL may further overlap at least the lower surface LS of the partition wall BW. The color layer ACL may further overlap at least the outer side surface OS of the partition wall BW. The color layer ACL may cover the reflective layer ML.

The first light control pattern CCF-R may be arranged in the first opening BW-OPR of the partition wall BW. The first light control pattern CCF-R may be in contact with the color layer ACL.

The fifth insulating layer 50 may be arranged under the color layer ACL. The fifth insulating layer 50 may encapsulate the color layer ACL and the first light control pattern CCF-R and may include an inorganic layer.

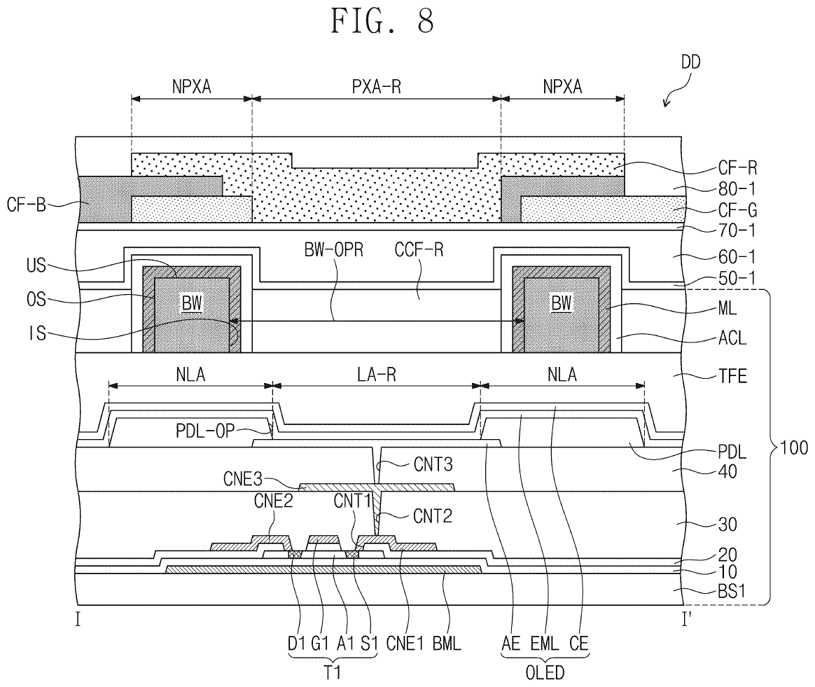

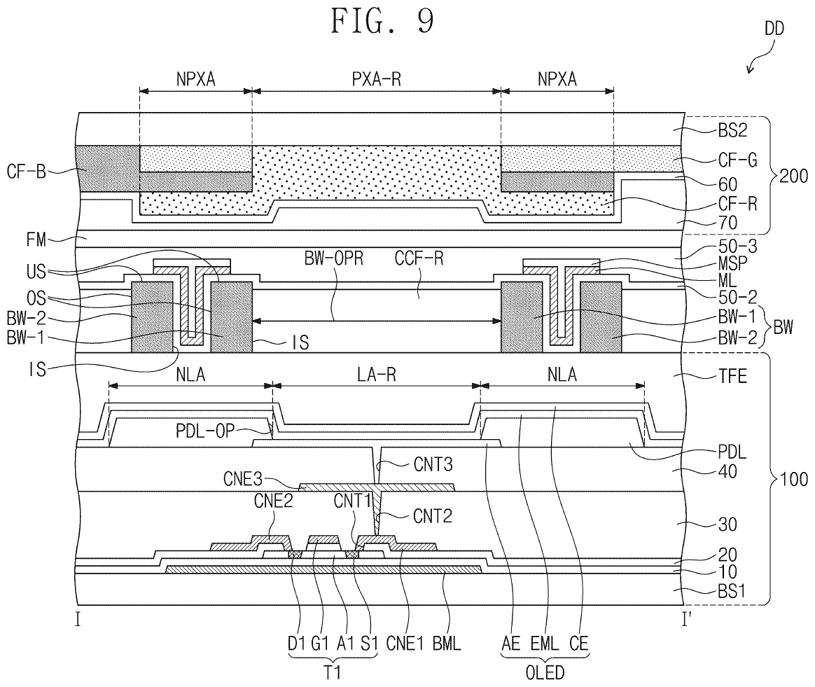

FIGS. 8 and 9 are cross-sectional views of display devices according to one or more embodiments of the present disclosure. In FIGS. 8 and 9, detailed descriptions of the same elements as those described with reference to FIGS. 1A to 5C will not be provided. Hereinafter, different features from those of the display device DD described with reference to FIGS. 5A to 5C will be described with reference to FIGS. 8 and 9.

Referring to FIG. 8, the display device may include one first base layer BS1. The display device DD may be formed by forming components on one first base layer BS1 through successive processes without the coupling process of the display panel 100 and the encapsulation panel 200 described with reference to FIG. 5A.

A fifth insulating layer 50-1 may encapsulate a partition wall BW and a first light control pattern CCF-R. As an example, the fifth insulating layer 50-1 may be an inorganic layer.

A sixth insulating layer 60-1 may be arranged on the fifth insulating layer 50-1. The sixth insulating layer 60-1 may serve as a planarization layer and may have a refractive index equal to or greater than about 1.1 and equal to or smaller than about 1.5. The refractive index of the sixth insulating layer 60-1 may be adjusted depending on a rate of hollow inorganic particles and/or a void in the sixth insulating layer 60-1. The sixth insulating layer 60-1 may provide a source light and a converted light more vertically.

A seventh insulating layer 70-1 may be arranged on the sixth insulating layer 60-1. The seventh insulating layer 70-1 may be an inorganic layer that encapsulates structures arranged thereunder. The seventh insulating layer 70-1 may not be provided.

A first color filter CF-R, a second color filter CF-G, and a third color filter CF-B may be arranged on the seventh insulating layer 70-1. An eighth insulating layer 80-1 may be arranged on the first color filter CF-R, the second color filter CF-G, and the third color filter CF-B, and the eighth insulating layer 80-1 may cover the first color filter CF-R, the second color filter CF-G, and the third color filter CF-B and may provide a flat surface. The eighth insulating layer 80-1 may be an organic layer.

In some embodiments, a shape and an arrangement of the partition wall BW if (e.g., when) viewed in the plane are substantially the same as those of the partition wall BW described with reference to FIGS. 5A to 6C.

Referring to FIG. 9, the display device DD, like the display device DD described with reference to FIG. 5A, according to the present embodiment may include a display panel 100, an encapsulation panel 200, and a filling material FM. In the present embodiment, detailed descriptions of the same elements as those described with reference to FIG. 5A will not be provided.

The partition wall BW may be arranged on the thin film encapsulation layer TFE. The partition wall BW may include an inner partition wall BW-1 and an outer partition wall BW-2. The inner partition wall BW-1 may be the first partition wall BW1 shown in FIGS. 6A to 6C, and the outer partition wall BW-2 may be around (e.g., surround) the inner partition wall BW-1 if (e.g., when) viewed in the plane. The inner partition wall BW-1 and the outer partition wall BW-2 may be arranged spaced and/or apart (e.g., spaced apart or separated) from each other if (e.g., when) viewed in the plane.

According to the present embodiment, different from the display device DD described with reference to FIG. 5A, the color layer ACL is omitted, and the partition wall BW may act as the color layer ACL. According to one or more embodiments, the partition wall BW may have the same color as the source light. The partition wall BW may have the blue color.

A fifth insulating layer 50-2 may be arranged on the partition wall BW. The fifth insulating layer 50-2 may encapsulate a first light control pattern CCF-R and the partition wall BW. The fifth insulating layer 50-2 may include an inorganic layer.

Referring to FIG. 9, a first opening BW-OPR may be defined through the inner partition wall BW-1, and the first light control pattern CCF-R may be formed in the first opening BW-OPR. A surface of the inner partition wall BW-1, which faces the first light control pattern CCF-R, may be defined as an inner side surface IS of the inner partition wall BW-1. A surface of the inner partition wall BW-1, which faces the outer partition wall BW-2, may be defined as an outer side surface OS of the inner partition wall BW-1. In some embodiments, a surface of the outer partition wall BW-2, which faces the inner partition wall BW-1, may be defined as an inner side surface IS of the outer partition wall BW-2, and a surface of the outer partition wall BW-2, which does not face the inner partition wall BW-1, may be defined as an outer side surface OS of the outer partition wall BW-2. Definitions of upper surfaces US of the inner and outer partition walls BW-1 and BW-2 may each independently be the same as those described herein with reference to FIG. 5A, so details thereof are omitted.

According to the present embodiment, a reflective layer ML may be arranged to correspond to the outer side surface OS and the upper surface US of the inner partition wall BW-1. According to the present embodiment, the reflective layer ML may also be arranged to correspond to the inner side surface IS and the upper surface US of the outer partition wall BW-2.

The source light emitted from the light emitting element OLED may travel upwardly. A portion of the source light may be provided to the first light control pattern CCF-R arranged inside the first opening BW-OPR, and a color of the portion of the source light may be converted by a quantum dot included in the first light control pattern CCF-R.

The other portion of the source light may be incident to the inner partition wall BW-1 and then may be reflected by the reflective layer ML. The reflected light reflected by the reflective layer ML may be incident to the first light control pattern CCF-R again after passing through the inner partition wall BW-1. Accordingly, the light conversion efficiency of the source light may be improved, and the front luminance may be improved.

The partition wall BW may be to absorb a portion of the light incident thereto from the outside of the display panel 100. Because the first color filter CF-R transmits the red light in natural light, the red light passing through and exiting from the first color filter CF-R may be absorbed by the partition wall BW. For example, the first color filter CF-R may allow red light from natural sources, such as sunlight, to pass through it. That is, this filter is designed to allow red wavelengths of light pass through while blocking or absorbing wavelengths of light of other colors. Therefore, the accuracy of the red color being displayed (e.g., on the screen) may be enhanced or improved. Therefore, the reflection phenomenon in which the red light incident from the outside is reflected by the reflective layer ML and then travels to the outside may be prevented or reduced.

Referring to FIG. 9, an organic material pattern MSP may be further arranged on the reflective layer ML. The organic material pattern MSP may include a base resin and an additive and may act as a mask in a process of forming the reflective layer ML. The reflective layer ML and the organic material pattern MSP may have substantially the same shape as each other if (e.g., when) viewed in the plane. The organic material pattern MSP may include the black coloring agent. The organic material pattern MSP may be to absorb the external light incident to the reflective layer ML.

A planarization layer 50-3 may be further arranged on the organic material pattern MSP and the fifth insulating layer 50-2. The planarization layer 50-3 may include an organic layer and may provide a flat surface.

According to the display panel 100 shown in FIG. 9, the process of forming the color layer ALC may not be provided compared to the display panel 100 shown in FIG. 5A. The partition wall BW including the inner partition wall BW-1 and the outer partition wall BW-2 of FIG. 9 may be formed through substantially the same process as the process of forming the partition wall BW of FIG. 5A.

Then, the first light control pattern CCF-R may be formed in the first opening BW-OPR of the inner partition wall BW-1. The first light control pattern CCF-R may be formed through an inkjet process.

The fifth insulating layer 50-2 may be formed to cover the first light control pattern CCF-R and the partition wall BW. The fifth insulating layer 50-2 may be formed by depositing an inorganic material through a deposition process. Then, the reflective layer ML may be formed. The reflective layer ML may be formed in a space between the outer side surface OS of the inner partition wall BW-1 and the inner side surface IS of the outer partition wall BW-2 through the sputtering process. The organic material pattern MSP and the fifth insulating layer 50-2 may be sequentially formed.

In one or more embodiments, the display device may be a component of and/or applied to electronic devices such as smartphones, televisions, monitors, tablets, electric vehicles, mobile phones, tablet personal computers (PC), mobile communication terminals, electronic notebooks, electronic books, portable multimedia players (PMP), navigation devices, ultra-mobile personal computers (UMPC), laptop computers, billboards, Internet of Things (IoT) devices, smartwatches, watch phones, or head-mounted displays (HMD). For example, the display device DD may be applied to a display unit of a television, a laptop computer, a monitor, a billboard, or the Internet of Things (IoT). Alternatively, in one or more embodiments, the display device DD may be applied to a smartwatch, a watch phone, and/or a head-mounted display device (HMD) for implementing virtual reality and/or augmented reality.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display device, electronic device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display and/or electronic device may be formed on one integrated circuit (IC) chip or on separate IC chips. Further, the one or more suitable components of the display and/or electronic device may be implemented on a flexible printed circuit film, a tape carrier package (TCP), a printed circuit board (PCB), or formed on one substrate. Further, the one or more suitable components of the display and/or electronic device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

Although one or more embodiments of the present disclosure have been described, it is understood that the present disclosure should not be limited to these embodiments but one or more suitable changes and modifications can be made by one ordinary skilled in the art within the spirit and scope of the present disclosure as hereinafter claimed.

Therefore, the disclosed subject matter should not be limited to any single embodiment described herein, and the scope of the present present disclosure shall be determined according to the attached claims, and equivalents thereof.

What is claimed is:

1. A display device comprising:
a first base layer;
a first light emitting element and a second light emitting element, each of the first and second light emitting elements being on the first base layer and configured to emit a source light;
a first partition wall through which a first opening is defined, the first opening corresponding to the first light emitting element;
a first light control pattern inside the first opening;
a reflective layer on at least an inner side surface of the first partition wall that defines the first opening; and
a color layer on the reflective layer, the color layer being to overlap at least the inner side surface of the first partition wall and to absorb a light incident thereto from an outside of the display device.

2. The display device of claim 1, wherein the reflective layer is further on an upper surface of the first partition wall.

3. The display device of claim 2, wherein the color layer is on the reflective layer to further overlap the upper surface of the first partition wall.

4. The display device of claim 3, wherein the reflective layer comprises:
a first portion on the inner side surface of the first partition wall; and
a second portion overlapping the upper surface of the first partition wall, and
wherein the color layer entirely overlaps the first portion and the second portion.

5. The display device of claim 4, further comprising:
a second partition wall through which a second opening is defined, the second opening corresponding to the second light emitting element; and
a second light control pattern inside the second opening, wherein the reflective layer is further on an inner side surface of the second partition wall that defines the second opening, and the color layer is on the reflective layer to further overlap the inner side surface of the second partition wall.

6. The display device of claim 1, wherein the reflective layer is further on an outer side surface of the first partition wall.

7. The display device of claim 6, wherein the color layer is on the reflective layer to further overlap the outer side surface of the first partition wall.

8. The display device of claim 1, wherein the source light is a blue light.

9. The display device of claim 8, wherein the first light control pattern comprises a quantum dot to convert the blue light to a red light or a yellow light.

10. The display device of claim 1, wherein a color of the color layer is the same as a color of the source light.

11. The display device of claim 1, wherein the first partition wall comprises a light shielding material.

12. The display device of claim 1, wherein the reflective layer comprises at least one selected from the metal group consisting of aluminum, silver, gold, platinum, copper, and palladium.

13. The display device of claim 1, further comprising a thin film encapsulation layer on the first base layer and to encapsulate the first light emitting element and the second light emitting element, wherein the first partition wall is on the thin film encapsulation layer.

14. The display device of claim 1, further comprising a first color filter on the first light control pattern, wherein the first color filter has a color different from the color of the color layer.

15. The display device of claim 1, further comprising a first color filter on the first light control pattern and an encapsulation panel opposite to the first base layer, wherein the first color filter is on a lower surface of the encapsulation panel.

16. A display device comprising:
a base layer;
a first light emitting element and a second light emitting element, each of the first and second light emitting elements being on the base layer and configured to emit a source light;
a partition wall through which an opening is defined, the opening corresponding to the first light emitting element;
a light control pattern in the opening; and
a reflective layer configured to an outer side surface of the partition wall and an upper surface of the partition wall, wherein a color of the partition wall is the same as a color of the source light.

17. The display device of claim 16, wherein the partition wall is configured to transmit the source light and absorb a light incident thereto from an outside of the display device.

18. The display device of claim 16, further comprising a color filter on the light control pattern.

19. An electronic device comprising:
display device comprising:
a first base layer;
a first light emitting element and a second light emitting element, each of the first and second light emitting elements being on the first base layer and configured to emit a source light;
a first partition wall through which a first opening is defined, the first opening corresponding to the first light emitting element;
a first light control pattern inside the first opening;
a reflective layer on at least an inner side surface of the first partition wall that defines the first opening; and
a color layer on the reflective layer, the color layer being to overlap at least the inner side surface of the first partition wall and to absorb a light incident thereto from an outside of the electronic device.

20. The electronic device of claim 19, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
